(19) United States
(12) Patent Application Publication
(10) Pub. No.: US 2025/0349669 A1
(43) Pub. Date: Nov. 13, 2025

(54) Liquid Jet Impingement Cooler

(71) Applicant: Purdue Research Foundation, West Lafayette, IN (US)

(72) Inventors: Gopinath Sahu, West Lafayette, IN (US); Justin Weibel, West Lafayette, IN (US); Tiwei Wei, Lafayette, IN (US)

(73) Assignee: Purdue Research Foundation, West Lafayette, IN (US)

(21) Appl. No.: 19/198,772

(22) Filed: May 5, 2025

Related U.S. Application Data
(60) Provisional application No. 63/643,573, filed on May 7, 2024.

(51) Int. Cl. H01L 23/427; H01L 21/48; H01L 23/433

(52) U.S. Cl. CPC H01L 23/427; H01L 21/4871; H01L 23/4336

(57) ABSTRACT

A liquid jet impingement cooler includes a wick structure formed of a porous material and a manifold. The manifold includes a plurality of inlet nozzles fluidly connecting a liquid inlet to the wick structure, a plurality of outlet nozzles fluidly connecting the wick structure to a liquid outlet, and a vapor outlet fluidly connected to the porous material of the wick structure.

This application claims priority to U.S. Provisional Application Ser. No. 63/643,573 entitled “Liquid and Vapor Separation in Liquid Jet Impingement Cooler for Low Surface Tension Fluids” filed May 7, 2024, the disclosure of which is incorporated herein by reference in its entirety.

### GOVERNMENT LICENSE RIGHTS

This invention was made with government support under DE-AR0001757 awarded by the Department of Energy. The government has certain rights in the invention.

### FIELD

The device and method disclosed in this document relates to a liquid jet impingement cooling systems and, more particularly, a liquid jet impingement cooler for an electronic device.

### BACKGROUND

Unless otherwise indicated herein, the materials described in this section are not admitted to be the prior art by inclusion in this section.

A liquid jet impingement cooler is a cooling system designed to dissipate heat generated by electronic devices, for example integrated circuits (ICs). In such a cooler, a liquid coolant is pumped through channels or nozzles to create a high-velocity jet that impinges directly onto the surface of the IC. This direct contact enhances heat transfer efficiency by effectively removing heat from the IC. The cooler may consist of a manifold for distributing the coolant and a series of nozzles or channels positioned above the IC surface. The liquid coolant absorbs heat from the IC, which causes it to evaporate/boil and decrease the surface temperature of the IC. The heated coolant then moves away from the IC surface, either by boiling/evaporation or forced circulation, allowing the heat to be dissipated elsewhere in the cooling system.

### SUMMARY

In one embodiment, a liquid jet impingement cooler for an electronic device including a wick structure formed of a porous material and a manifold. The manifold includes a plurality of inlet nozzles fluidly connecting a liquid inlet to the wick structure, a plurality of outlet nozzles fluidly connecting the wick structure to a liquid outlet, and a vapor outlet fluidly connected to the porous material of the wick structure.

In another embodiment, an integrated circuit includes a semiconductor die and a cooler including a wick structure formed of a porous material applied directly on a surface of the semiconductor die, and a manifold. The manifold includes a plurality of inlet nozzles fluidly connecting a liquid inlet of the cooler to the wick structure, a plurality of outlet nozzles fluidly connecting the wick structure to a liquid outlet of the cooler, and a vapor outlet fluidly connected to the porous material of the wick structure.

In some embodiments, a method of forming a cooler includes forming a wick structure of a porous material directly onto a surface of an electronic device; forming a plurality of inlet nozzles and a plurality of outlet nozzles of a manifold onto the wick structure; and enclosing the wick structure, the plurality of inlet nozzles, and the plurality of outlet nozzles such that the plurality of inlet nozzles fluidly connect a liquid inlet of the cooler to the wick structure, the plurality of outlet nozzles fluidly connect the wick structure to a liquid outlet of the cooler, and a vapor outlet of the cooler is fluidly connected to the porous material of the wick structure.

### BRIEF DESCRIPTION OF THE DRAWINGS

The foregoing aspects and other features of the liquid jet impingement cooler are explained in the following description, taken in connection with the accompanying drawings.

FIG. 1 is a schematic cross-sectional view of a liquid jet impingement cooler according to the disclosure.

FIG. 2 is a cross-sectional solid model view of the liquid jet impingement cooler of FIG. 1.

FIG. 3 is an exploded perspective view of the liquid jet impingement cooler of FIG. 1.

FIG. 4 is a perspective view of the liquid jet impingement cooler of FIG. 1.

FIG. 5 is a top plan view of the wick structure of the liquid jet impingement cooler of FIG. 1.

FIG. 6 is a top perspective view of one unit cell of the wick structure of the liquid jet impingement cooler of FIG. 1 arranged on an electronic device.

FIG. 7 is a top perspective view of one unit cell of the wick structure the liquid jet impingement cooler of FIG. 1 with the associated manifold components.

FIG. 8 is a cross-sectional view of a channel formed by the wick structure and a cover plate of the liquid jet impingement cooler of FIG. 1.

FIG. 9 is a schematic representation of a cooling system that includes the liquid jet impingement cooler.

FIG. 10 depicts a graph of experimental estimations of (a) pressure drop vs. vapor quality and (b) total pressure loss at the liquid inlet, liquid outlet, and vapor outlet.

FIG. 11 depicts graphs of experimental estimations of wicking length against heat flux at (a) different porosity fractions and (b) different pore diameters.

FIG. 12 is a process diagram of a method for manufacturing the liquid jet impingement cooler of FIG. 1.

FIG. 13a is a top perspective view of a semiconductor die.

FIG. 13b is a side elevational view of the semiconductor die of FIG. 13a.

FIG. 13c is a top perspective view of one unit cell of the wick structure applied to the semiconductor die of FIG. 13a.

FIG. 13d is a side elevational view of the unit cell of the wick structure applied to the semiconductor die of FIG. 13a.

FIG. 13e is a is a top perspective view of the unit cell of FIG. 13c after application of the inlet and outlet nozzles the wick structure.

FIG. 13f is a side elevational view of the unit cell of FIG. 13c after application of the inlet and outlet nozzles to the wick structure.

FIG. 13g is a is a top perspective view of the unit cell of FIG. 13e after application of the cover plates to the wick structure.

FIG. 13h is a side elevational view of the unit cell of FIG. 13e after application of the cover plates to the wick structure.

FIG. 14 is, in the upper illustrations, a series of scanning electron microscope pictures at different magnification levels of one example of the wick structure, and in the lower illustrations, CT scan images at different locations of the example wick structure.

### DETAILED DESCRIPTION

For the purposes of promoting an understanding of the principles of the disclosure, reference will now be made to the embodiments illustrated in the drawings and described in the following written specification. It is understood that no limitation to the scope of the disclosure is thereby intended. It is further understood that the present disclosure includes any alterations and modifications to the illustrated embodiments and includes further applications of the principles of the disclosure as would normally occur to one skilled in the art to which this disclosure pertains.

### System Overview

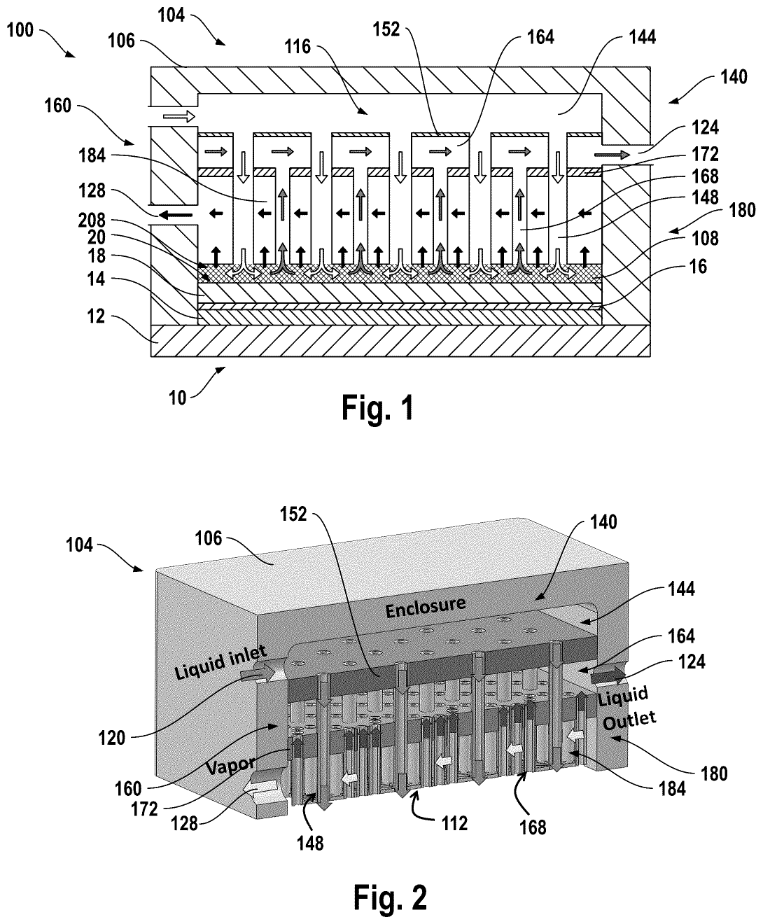

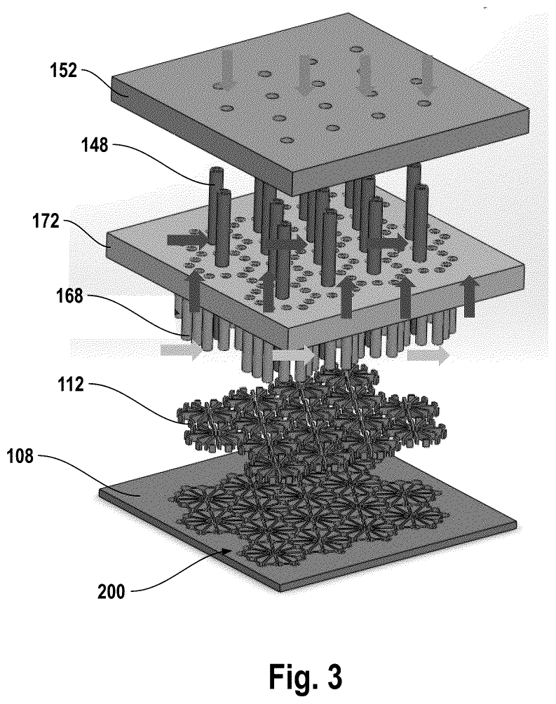

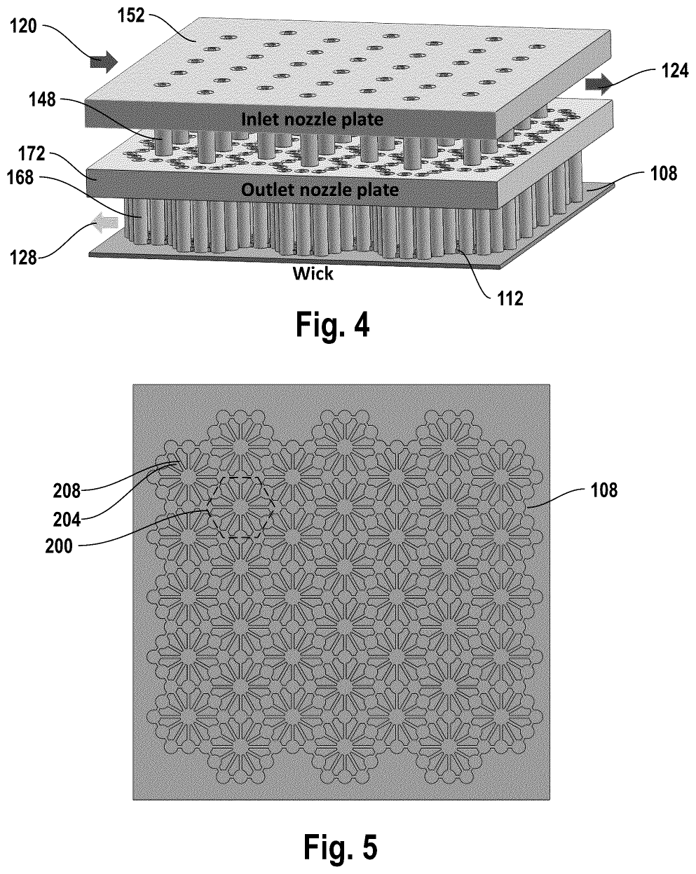

FIG. 1 illustrates a schematic cross-sectional view of a liquid jet impingement cooler 100, FIG. 2 depicts the liquid jet impingement cooler 100 as a solid model, FIG. 3 depicts the liquid jet impingement cooler 100 in an exploded perspective view, and FIG. 4 illustrates a perspective view of the liquid jet impingement cooler 100. The liquid jet impingement cooler 100 is configured to remove a thermal load generated from a heat-generating electronic device 10, for example an integrated circuit, to improve the operation and durability of the device 10. In particular, the liquid jet impingement cooler 100 may be applied to a device 10 having a substrate 12, and several layers 14, 16, 18, including an upper die layer 18. The integration of the disclosed capillary-assisted boiling enhancement and phase separation into the liquid jet impingement cooler 100 provides an improvement in thermal management technology.

The liquid jet impingement cooler 100 includes a manifold 104 contained within an enclosure 106, a wick structure 108, and a plurality of cover plates 112, which are stacked on the device 10. The manifold 104 serves as a conduit for flow of coolant 116, directing the coolant 116 from a liquid inlet 120 to a liquid outlet 124 and a vapor outlet 128, while enabling the coolant 116 to impinge on the heated surface 20 of the device 10 to absorb heat therefrom. The coolant 116 may be any suitable refrigerant, including for example R1233zd, which is particularly desirable as a refrigerant because R1233zd is non-flammable, non-toxic, has low global warming potential, and little or no ozone depletion potential. R1233zd has relatively low surface tension, which may cause problems in some systems. The liquid jet impingement cooler 100 is designed to facilitate cooling using low surface tension coolants such as R1233zd. The reader should appreciate, however, that other refrigerants, including low surface tension refrigerants such as, for example, other hydrofluoroolefins (HFOs) such as R1234ze (E), R1234zf, certain hydrochlorofluorocarbon (HCFC) refrigerants, and natural refrigerants such as CO₂, may be used in the liquid jet impingement cooler 100.

The manifold 104 has a top level 140, which includes the liquid inlet 120, an inlet chamber 144 fluidly connected to the liquid inlet 120, a plurality of inlet nozzles 148 that fluidly connect the inlet chamber 144 to the wick structure 108, and an inlet nozzle plate 152. An intermediate level 160 of the manifold 104 includes the liquid outlet 124, a liquid outlet plenum 164 fluidly connected to the liquid outlet 124, a plurality of outlet nozzles 168 that connect the liquid outlet plenum 164 to the wick structure 108, and an outlet nozzle plate 172. In particular, the plurality of outlet nozzles 168 open into the liquid outlet plenum 164. Further, the manifold 104 has a lower level 180 that includes the vapor outlet 128 and a vapor plenum 184, which is fluidly connected to the vapor outlet 128.

The inlet chamber 144 and the liquid outlet plenum 164 are fluidly isolated from one another by the inlet nozzle plate 152, through which the plurality of inlet nozzles 148 pass. Similarly, the liquid outlet plenum 164 and the vapor plenum 184 are fluidly isolated from one another by the outlet nozzle plate 172, through which both the plurality of inlet nozzles 148 and the plurality of outlet nozzles 168 pass. Thus, the liquid outlet plenum 164 and the vapor plenum 184 are connected to one another only through the wick structure 108.

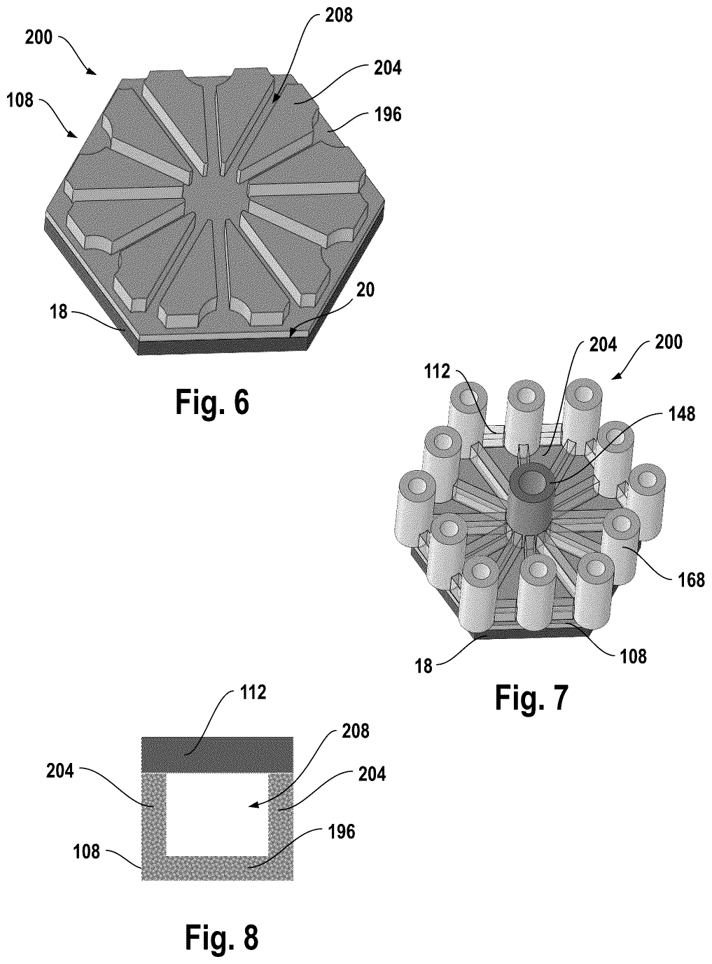

As is best seen in FIGS. 5-8, the wick structure 108 includes a substantially planar base portion 196 formed directly on the surface 20 of the semiconductor die 18 of the electronic device 10. The wick structure 108 also includes a plurality of unit cells 200, each of which is fluidly connected to one of the plurality of inlet nozzles 148 and to a multiplicity of the outlet nozzles 168, which are each shared between adjacent unit cells 200. In particular, in the illustrated embodiment, each one of the plurality of unit cells 200 is hexagonally shaped, and is connected to twelve outlet nozzles 168.

In addition, each unit cell 200 of the wick structure 108 includes a plurality of porous projections 204 that project upwardly from the base portion 196. A channel 208 is defined between each adjacent pair of porous projections 204 in the unit cell 200 and the base portion 196 of the wick structure 108 so as to connect the inlet nozzle 148 of the unit cell 200 to the associated outlet nozzles 168 in the unit cell 200. In particular, the porous projections 204 form the side walls of the channels 208, while the base portion 196 forms the bottom walls of the channels 208. The wick structure 108, and in particular the porous projections 204, may be, in some embodiments, fabricated directly onto the upper surface 20 of the semiconductor die 18 of the device 10 having the integrated circuit by, for example, additive manufacturing.

Further, the cover plates 112 forms the top walls of the channels 208 such that, as best illustrated in FIG. 8, the cover plates 112 directly cover over the grooves formed in the wick structure 108 between the porous projections 204. Particularly, the cover plates 112 only close over the channels 208, and the remaining three faces defining the channels 208 are hydraulically connected to wick structure 108. The coolant 116 that does not pass through the channels 208 directly from the inlet nozzles 148 to the outlet nozzles 168 enters into the micropores of the wick structure 108. As will be discussed in detail below, the fraction of coolant 116 flowing through wick structure 108 can be controlled through pressure balancing by utilizing valves connected to the outlet liquid/vapor lines.

In one hexagonal unit cell 200, detailed in FIG. 7, there are 12 outlet nozzles 168 connected to one inlet nozzle 148. The outlet nozzles 168 are connected through grooves in the wick structure 108 that are capped by the cover plates 112, effectively forming the channels 208 through the wick structure 108. The channels 208 serve as liquid reservoirs distributed throughout the surface from which the exposed wick structure 108 can draw fluid by capillary action, similar to the liquid bypass through a compensation chamber in a pump-assisted capillary evaporator. In particular, in the wick structure 108, the liquid bypass occurs at the evaporator surface and with fine-length-scale feature patterning, such that the capillary wicking distance is less than the size of the unit cell 200, thereby enabling operation with low-surface tension liquids that provide minimal capillary pressure. Further, the unit cell configuration and the distribution of the plurality of inlet nozzles 148, enables relatively uniform liquid distribution across the evaporator heated area.

As discussed in detail below, the wick structure 108 may be formed by, for example, additive manufacturing. In particular, the wick structure 108 may be formed of a plurality of packed microspheres deposited directly onto the semiconductor die 18, with spacing between the microspheres configured to enable the desired porosity in the wick structure 108. In particular, the porosity of the wick structure 108 may be between approximately 0.15 and approximately 0.75. In one embodiment, the porosity of the wick structure 108 may be between approximately 0.20 and approximately 0.50. In another embodiment, the porosity of the wick structure 108 may be between approximately 0.35 and approximately 0.45. The pore size or pore diameter in the wick structure 108 may be in the single digit micron range to hundreds of microns or, in other words, between 1 micron and 1000 microns. In another embodiment, the pore size or pore diameter in the wick structure 108 may be between approximately 1 micron and approximately 100 microns. In yet another embodiment, the pore size or pore diameter may be between approximately 5 microns and approximately 55 microns.

The manifold 104 is configured such that relatively cold coolant 116 flows into inlet chamber 144 of the top level 140 via the liquid inlet 120, and subsequently flows through the plurality of inlet nozzles 148 to the channels 208 defined by the wick structure 108 and the associated cover plate 112. Because of the distributed configuration of the unit cell structure 200, the coolant 116 is distributed across the surface 20 of the semiconductor die 18, such that the heat from the semiconductor die 18 is transferred directly to the coolant 116 across the surface 20 of the semiconductor die 18.

As the heat from the semiconductor die 18 is transferred to the coolant 116, a portion of the coolant 116 undergoes a phase-change. The porous wick structure 108 has a considerable internal surface area, thereby providing an abundance of nucleation sites, allowing consistent and uniform boiling throughout the liquid jet impingement cooler 100. Since heat is required to change the phase of the coolant 116, the boiling of the coolant allows the coolant 116 to absorb additional heat from the semiconductor die 18.

The effective exit vapor quality of the system depends on the impinging coolant flow rate and the operating heat flux conditions. If the liquid and vapor portion of the coolant 116 were allowed to exit through a single common outlet, the generated mixture of liquid and vapor would introduce pressure fluctuations and flow instabilities into the flow of the system. However, in the liquid jet impingement cooler 100, the liquid and vapor phases are separated via strategic integration of the manifold 104 with the wick structure 108 and pressure balancing between outlet vapor and liquid. The liquid and vapor portions are separated from one another by the porous material of the wick structure 108, thereby avoiding the mixing of the exiting liquid and vapor. The generated vapor passes through the porous wick structure 108 to the vapor plenum 184, and is directed towards the vapor outlet 128. The remaining mass fraction of liquid coolant that does not evaporate is directed from the channels 208 through the plurality of outlet nozzles 168 and the liquid outlet plenum 164 to the liquid outlet 124.

The phase-separation of the coolant 116 is achieved in the liquid jet impingement cooler 100 by controlling the backpressure imposed on the liquid and vapor pathways during two-phase operation, combined with the aforementioned strategic patterning of the wick structure 108 aligned with the array of inlet and outlet nozzles 148, 168. In particular, due to the integration within the wick structure 108 of the embedded capped channels 208, which connect the plurality of inlet nozzles 148 to the plurality of outlet nozzles 168, the liquid jet impingement cooler 100 enables control over the liquid pathways in the liquid jet impingement cooler 100. When saturated liquid coolant 116 from the inlet nozzle 148 impinges at the center of the wick structure 108, a significant fraction of the coolant 116 flows through the channels 208 connecting the plurality of inlet nozzles 148 and the plurality of outlet nozzles 168, since the channels 208 offer the path of least hydraulic-resistance to the exit, as compared to flowing through the much smaller pore sizes of the wick structure 108.

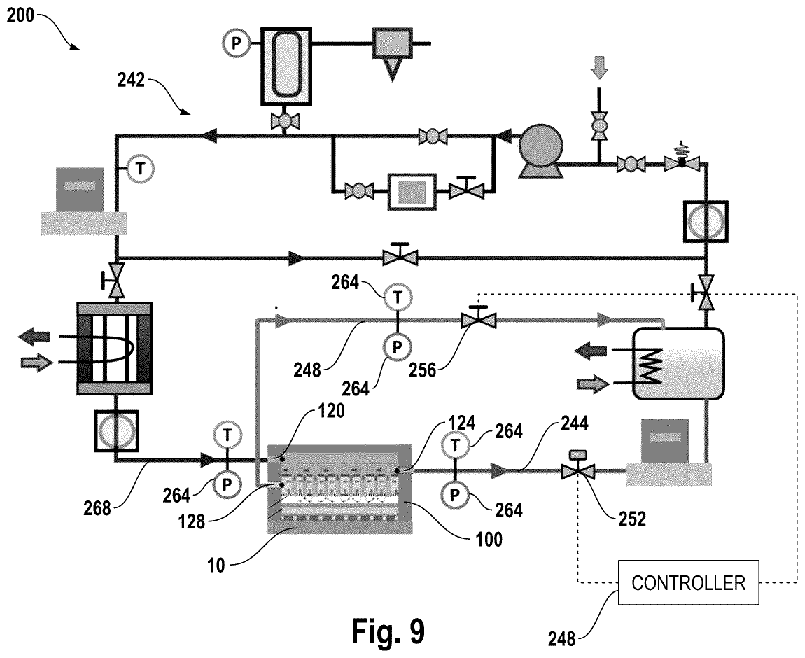

FIG. 9 depicts a schematic representation of a cooling system 240 for the liquid jet impingement cooler 100. The cooling system 240 has a cooling loop 242 that forms a refrigeration circuit connecting the liquid outlet 124 and the vapor outlet 128 to the liquid inlet 120 via a series of refrigeration components, e.g. a condenser, an expansion valve, a pump or compressor, one or more heat exchangers, and a plurality of valves, to circulate the coolant 116 and remove the heat absorbed by the liquid jet impingement cooler 100 from the coolant 116.

In particular, the liquid outlet 124 and the vapor outlet 128 are connected to a liquid outlet line 244 and vapor outlet line 248, respectively. A liquid E-valve 252 is positioned in the liquid outlet line 244, and a vapor E-valve 256 is positioned in the vapor outlet line 248. The cooling system 240 includes a controller 260 configured to operate the valves 252, 256. In particular, the controller 260 adjusts the position of the E-valve 252 to control the liquid outlet flow rate from the liquid outlet 124 and apply back-pressure to the liquid outlet 124 based on signals received from one or more temperature or pressure sensors 264 arranged in a liquid inlet line 268, the vapor outlet line 248, and/or the liquid outlet line 244. In addition, the controller 260 may also be configured to adjust the position of the E-valve 256 to control the vapor outlet flow rate from the vapor outlet 128 and apply back-pressure to the vapor outlet 128. Phase-separation can be achieved by controlling the back-pressure imposed on the liquid and vapor outlets 124, 128 during two-phase operation, combined with the aforementioned strategic patterning of the wick structures 108 aligned with the array of jet nozzles. Phase separation at the desired heat input is thereby achieved by equilibrating the pressure drops across the liquid and vapor outlet lines using the back-pressure control mechanisms, i.e. the E-valves 252, 256. In particular, in some embodiments, operation at even higher heat fluxes above the wicking limit is possible by applying back-pressure to mechanically pump additional liquid into the wick structure 108 by closing the E-valve 252 in the liquid outlet line 244.

Under unheated conditions, the coolant 116 would flood the channels 208 and fully saturate the remaining part of the wick structure 108. However, during two-phase operation, liquid coolant 116 forced into the wick structure 108 undergoes boiling and evaporation within the porous wick structure 108, and flow is then assisted by capillary action. If the relative backpressures on the liquid and vapor outlets 124, 128 are controlled such that all liquid flow into the wick structure 108 is evaporated at the corresponding heat input, only the vapor generated will exit through the portion of the wick structure 108, particularly the porous projections 204, exposed between the cover plates 112. As the channels 208 are always flooded with high momentum and nearly saturated liquid, the vapor quality at the outlet of the channels 208 remains nearly zero.

Phase separation at the desired heat input is thereby achieved by equilibrating the pressure drops across the liquid outlet 124 and the vapor outlet 128 using the aforementioned back-pressure control mechanism. The use of the three-path manifold 104 with phase separation can hence enable stable operation even under two-phase flow conditions.

### Experimental Analysis

The pressure drop and wicking length estimation are two parameters affecting the efficiency of the liquid jet impingement cooler. Several pressure drop components across the manifold are affected by the design parameters such as, for example, the pressure loss in the inlet chamber 144 and in the liquid outlet plenum 164, the pressure loss at the entrance to the plurality of inlet nozzles 148 and at the entrance to the plurality of outlet nozzles 168, the friction resistances in the plurality of inlet nozzles 148 and in the plurality of outlet nozzles 168, the expansion losses at the outlets of the plurality of inlet nozzles 148 and at the plurality of outlet nozzles 168, and the pressure loss due to the radial flow in the wick structure 108. A systematic analytical calculation was performed for various flow rates and heat flux conditions to estimate critical pressure drop components. It was found that the system pressure drop can be maintained below 40 kPa if the manifold is operated above a vapor quality of ˜ 0.25, even at the maximum heat flux conditions. Illustration (a) of FIG. 10 shows a pressure drop across the manifold for various vapor quality at a heat flux of 500 W/cm². Additionally, illustration (b) of FIG. 10 pressure drop of the individual components at the liquid inlet, outlet, and vapor outlet.

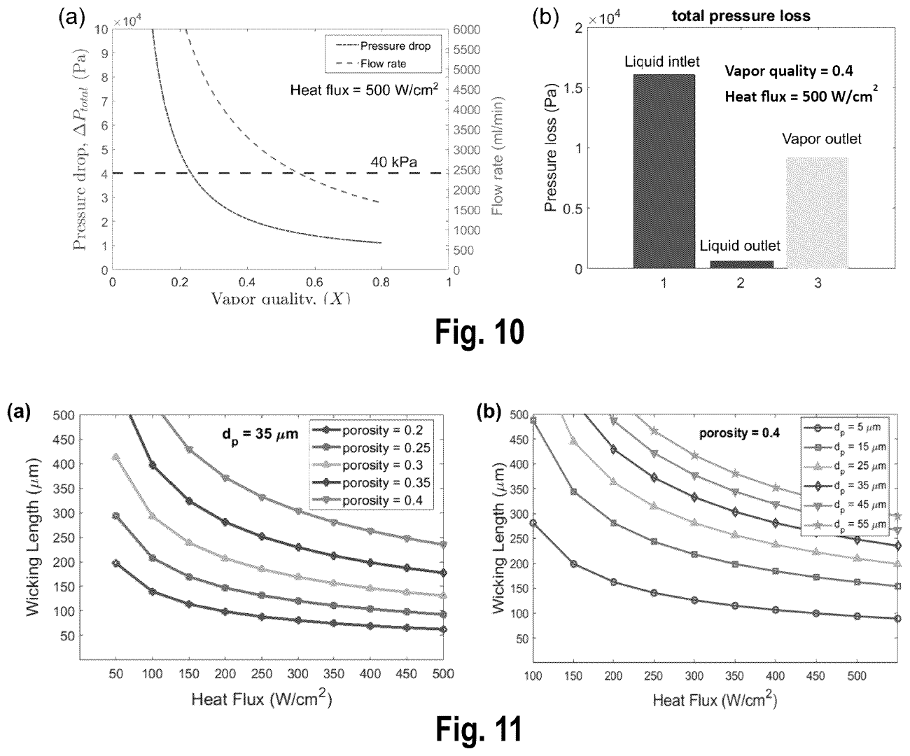

FIG. 11 shows experimental estimations of wicking length against heat flux at different pore diameters and porosity fractions. The wicking length is the maximum distance over which a liquid can be transported within the porous structure through capillary forces, overcoming viscous resistance. The wicking length influences the liquid supply to evaporation sites within the porous structure, thereby governing the thermal performance of the liquid jet impingement cooler 100. The embedded tunnels in the wick structure 108 are designed to distribute the liquid and ensure phase separation. Also, their spacing is selected such that the capillary wicking length into the porous wick structure 108 is sufficient even when low-surface-tension fluids are used as the working fluid. This design consideration avoids drying out of the wick structure 108 and ensures continuous evaporation at the target heat flux. In particular, the practical heat flux limit for such a configuration is the capillary limit, which is determined by the available capillary pumping head, properties of wick structures, and thermophysical parameters of the working fluid. The wicking length Lw can be calculated as:

$${L}_{W} = \sqrt{\frac{{Kt}_{wick} {ρ}_{l} {P}_{c} {h}_{fg}}{{μ}_{l} {q}^{″}}}$$

where K is the liquid permeability, q″ is heat flux, h_{fg} is latent heat, μₗ is liquid viscosity, μₗ is the density of the coolant, P_{c} is the capillary pressure, and t_{wick} is the thickness of the wick structure 108 in the direction perpendicular to the device 10 on which the wick structure 108 is formed. The liquid permeability K can be calculated as:

$$K = \frac{{d}_{p} {ϕ}^{3}}{180 {( 1 - ϕ )}^{2}}$$

where dₚ is the mean particle diameter and ϕ is the porosity. Additionally, the capillary pressure P_{c}, for low surface tension coolants, can be calculated as

$${P}_{c} = \frac{2 σ}{{r}_{c}}$$

where σ is the surface tension of the fluid and re is the effective pore radius, considered to be 0.21dₚ.

The chart in illustration (a) of FIG. 11 shows estimations of wicking length at different heat flux conditions for various porosities. Additionally, the chart in illustration (b) of FIG. 11 shows estimations of wicking length at different heat flux conditions for various particle diameter. The required wicking length for the experimentally tested design was approximately 270 μm, which can be achieved above a porosity of 0.3 even at the highest heat flux conditions. In addition, as discussed in detail above, the wicking length can be further increased during the operation by applying back pressure, which can be done by closing the E-valve in the liquid outlet line to assist capillary flow.

### Method for Manufacturing the Liquid Jet Impingement Cooler

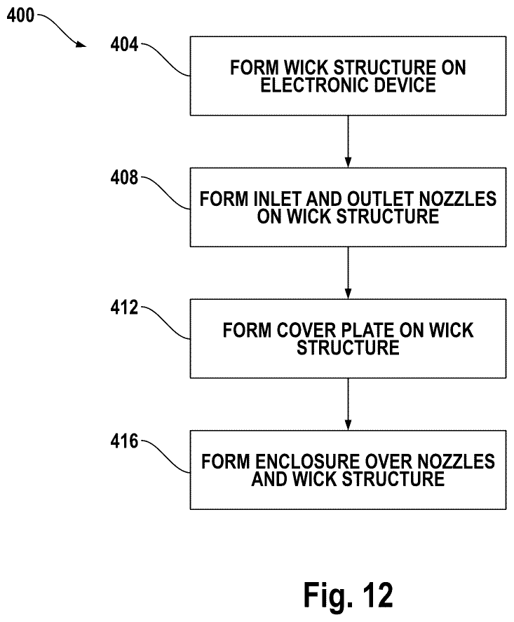

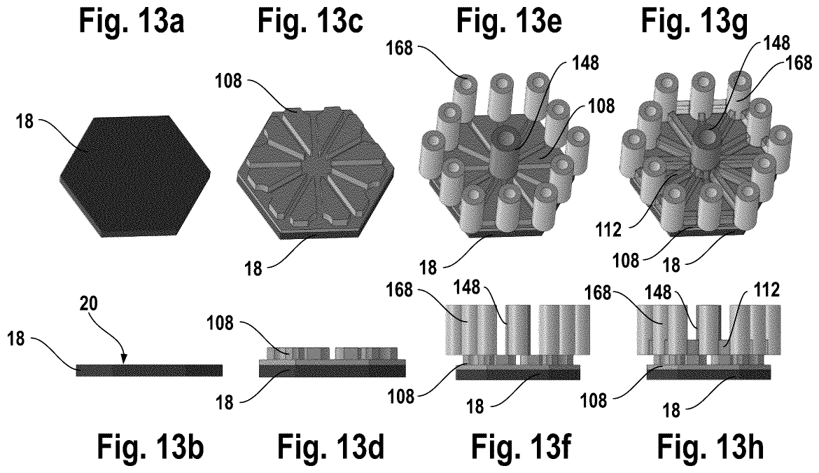

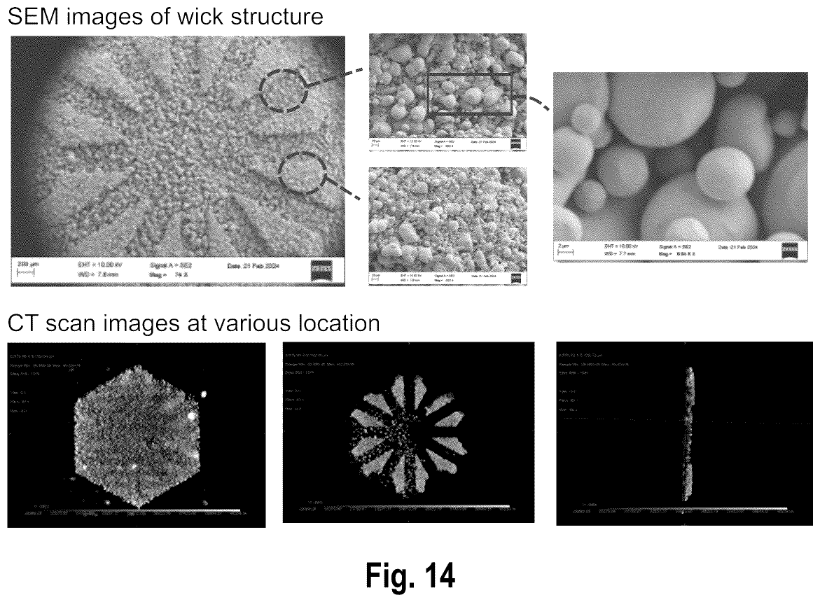

FIG. 12 illustrates a process diagram of a method 400 for manufacturing the manifold 104 of the liquid jet impingement cooler 100. The method 400 begins with an electronic device 10, in particular a semiconductor die 18, shown in FIGS. 13a and 13b. The wick structure 108 is then applied to the upper surface 20 of the semiconductor die 18, as shown in FIGS. 13c and 13d (block 404). In some embodiments, the wick structure 108 is applied to the semiconductor die 18 via an additive manufacturing process, for example a 3d printing process. In one particular embodiment, a vat polymerization method is used to print the wick structure 108 layer by layer. Further, in some configurations, the small area of the material ejected may be insufficient to support further layers, and the printing method may include inclining the semiconductor die 18 during the printing process. This approach also allows for printing the part without requiring support between the layers, making manufacturing easier without removing support materials between vertical plates. Additionally, printing at an incline helps to address overhanging issues with the poly jet technology method. The inner diameter of the printing nozzles may be, for example, on the micron level. For illustrative purposes, the upper illustrations shown in FIG. 14 depict one example of the wick structure 108 is depicted at various magnification levels using a scanning electron microscope (SEM), while the lower illustrations show CT scan images at various locations in the wick structure 108.

Referring back to FIG. 12, the method 400 further includes applying the inlet and outlet nozzles 148, 168 on the wick structure 108, as shown in FIGS. 13e and 13f (block 408). The inlet and outlet nozzles 148, 168 may be printed using the same additive manufacturing process as the formation of the wick structure 108, or it may be performed in a different method that allows for larger droplet size and/or faster manufacturing. In one embodiment, the inlet and outlet nozzles 148, 168 may be formed, for example, with diameters of approximately 0.6 mm and 0.5 mm, respectively.

The method 400 also includes forming the cover plates 112 on the wick structure 108 and between the inlet and outlet nozzles 148, 168, as shown in FIGS. 13g and 13h (block 412). Again, the cover plates 112 may be formed using the same additive manufacturing process as the formation of the wick structure 108 and/or the inlet and outlet nozzles 148, 168, or it may be performed in a different method.

Additionally, the method 400 includes forming the enclosure 106 around the wick structure 108 and the inlet and outlet nozzles 148, 168, and forming the inlet and outlet nozzle plates 152, 172 in the enclosure 106 (block 416). The enclosure 106 and nozzle plates 152, 172 may be separately formed, or they may also be made via an additive manufacturing process.

In some embodiments, any combination of the formation steps (blocks 404, 408, 412, 416) may be executed concurrently or, in other words, any layer of the layer-by-layer additive manufacturing may form more than one of the wick structure 108, the cover plates 112, the inlet and/or outlet nozzles 148, 168, the enclosure 106, and the nozzle plates 152, 172. For instance, because of the inclination of the build plate, the additive manufacturing process may include forming layers that include part of each of the wick structure 108, the cover plates 112, the inlet and outlet nozzles 148, 168, and the cover plates 112. In other embodiments, the wick structure 108 may be manufactured first, and then the components of the manifold 104 may be formed concurrently.

In one embodiment, the inlet and outlet nozzles 148, 168, the cover plates 112, and the enclosure 106 may be 3d printed using a resin material, while the wick structure 108 may be primarily formed of 3d printed copper powder. In some embodiments, the inlet and outlet nozzles 148, 168, the cover plates 112, the enclosure 106, and the nozzle plates 152, 172 may be formed of rigid resin such as, for example, Rigid 10K Resin from Formlabs®. However, the reader should appreciate that the wick structure 108 and the components of the manifold 104 may be formed of any material that is compatible with the coolant used in the liquid jet impingement cooler 100.

While the disclosure has been illustrated and described in detail in the drawings and foregoing description, the same should be considered as illustrative and not restrictive in character. It is understood that only the preferred embodiments have been presented and that all changes, modifications and further applications that come within the spirit of the disclosure are desired to be protected.

What is claimed is:

1. A cooler for an electronic device comprising:
a wick structure formed of a porous material; and
a manifold comprising:
a plurality of inlet nozzles fluidly connecting a liquid inlet to the wick structure;
a plurality of outlet nozzles fluidly connecting the wick structure to a liquid outlet; and
a vapor outlet fluidly connected to the porous material of the wick structure.

2. The cooler of claim 1, wherein the wick structure defines a plurality of channels fluidly connecting each one of the plurality of inlet nozzles to the plurality of outlet nozzles.

3. The cooler of claim 2, wherein the wick structure includes a substantially planar base portion and a plurality of projections that project away from the substantially planar base portion, each adjacent pair of the plurality of projections defining side walls of one of the plurality of channels.

4. The cooler of claim 3, wherein the manifold defines a liquid outlet plenum into which the plurality of outlet nozzles open and which fluidly connects the plurality of outlet nozzles to the liquid outlet.

5. The cooler of claim 4, wherein the manifold and the wick structure define a vapor plenum, which is fluidly connected to the vapor outlet, the vapor plenum being fluidly isolated from the liquid outlet plenum.

6. The cooler of claim 5, wherein the plurality of projections of the wick structure form a bottom surface of the vapor plenum.

7. The cooler of claim 6, wherein the manifold further comprises a plurality of cover plates, each of which defines a top side of an associated one of the plurality of channels.

8. The cooler of claim 7, wherein the manifold defines an inlet chamber into which the liquid inlet opens, the inlet chamber fluidly connecting the liquid inlet to the plurality of inlet nozzles.

9. The cooler of claim 7, wherein the wick structure includes a plurality of unit cells, each of which includes one of the plurality of inlet nozzles and portions of a multiplicity of the plurality of outlet nozzles.

10. The cooler of claim 9, wherein each of the plurality of unit cells is hexagonally shaped.

11. The cooler of claim 10, wherein the multiplicity of the plurality of outlet nozzles includes twelve outlet nozzles.

12. The cooler of claim 11, wherein each unit cell includes twelve channels of the plurality of channels, each of which connects the one of the plurality of inlet nozzles to one of the twelve outlet nozzles.

13. The cooler of claim 1, wherein the wick structure has a porosity of between approximately 0.15 and approximately 0.75 and a pore diameter of between approximately 1 micron and approximately 100 microns.

14. The cooler of claim 1, wherein the wick structure is formed of a plurality of microspheres.

15. A cooling system for an electronic device comprising:
the cooler of claim 1; and
a cooling loop forming a refrigeration circuit connecting the liquid inlet, the liquid outlet, and the vapor outlet to one another, the cooling loop including a liquid outlet line in which a valve is arranged, the valve configured to control a back pressure in the wick structure of the cooler.

16. An integrated circuit comprising:
a semiconductor die; and
a cooler comprising:
a wick structure formed of a porous material applied directly on a surface of the semiconductor die; and
a manifold comprising:
a plurality of inlet nozzles fluidly connecting a liquid inlet of the cooler to the wick structure;
a plurality of outlet nozzles fluidly connecting the wick structure to a liquid outlet of the cooler; and
a vapor outlet fluidly connected to the porous material of the wick structure.

17. A method of forming a cooler comprising:
forming a wick structure of a porous material directly onto a surface of an electronic device;
forming a plurality of inlet nozzles and a plurality of outlet nozzles of a manifold onto the wick structure; and
enclosing the wick structure, the plurality of inlet nozzles, and the plurality of outlet nozzles such that the plurality of inlet nozzles fluidly connect a liquid inlet of the cooler to the wick structure, the plurality of outlet nozzles fluidly connect the wick structure to a liquid outlet of the cooler, and a vapor outlet of the cooler is fluidly connected to the porous material of the wick structure.

18. The method of claim 17, wherein the forming of the wick structure includes using additive manufacturing to deposit the wick structure directly onto the surface of the electronic device.

19. The method of claim 18, wherein the forming of the plurality of inlet nozzles and the plurality of outlet nozzles includes using additive manufacturing to deposit the plurality of inlet nozzles and the plurality of outlet nozzles onto the wick structure.

20. The method of claim 17, further comprising forming a plurality of cover plates over grooves in the wick structure so as to form a plurality of channels, each of which connects one of the plurality of inlet nozzles to one of the plurality of outlet nozzles.
